(19) United States
(12) Patent Application Publication
(10) Pub. No.: US 2026/0026326 A1
(43) Pub. Date: Jan. 22, 2026

(54) SELECTIVE DEPOSITION OF LINER LAYER

(71) Applicant: Applied Materials, Inc., Santa Clara, CA (US)

(72) Inventors: Vamshi Krishna Gaddamedi, Santa Clara, CA (US); Abdul Aziz Khaja, Morganville, CA (US); Ligang Gao, Chandler, AZ (US); Karthik Colinjivadi, Dublin, CA (US); Muthukumar Kaliappan, Fremont, CA (US); Vahid Ghodsi Karbasdehi, Chandler, AZ (US); Michael Haverty, Mountain View, CA (US)

(73) Assignee: Applied Materials, Inc., Santa Clara, CA (US)

(21) Appl. No.: 18/775,081

(22) Filed: Jul. 17, 2024

(51) Int. Cl. H01L 21/768; H01L 21/02; H01L 21/3065

(52) U.S. Cl. CPC H01L 21/76831; H01L 21/02274; H01L 21/02527; H01L 21/0262; H01L 21/3065

(57) ABSTRACT

Methods of depositing a liner layer in a semiconductor device are described. In some embodiments, the method includes depositing a carbon layer including carbon on a substrate, the substrate having at least one feature including a sidewall surface and the carbon layer having a carbon surface; and selectively depositing the liner layer on the sidewall surface over the carbon surface. In other embodiments, the method includes depositing a carbon layer comprising carbon in a bottom second portion of a substrate feature selectively over a top first portion of the substrate feature, the top first portion having a sidewall surface, the carbon layer having a carbon surface; etching the carbon surface; and depositing the conformal layer on the sidewall surface of the top first portion, the conformal layer deposited on the sidewall surface selectively over the carbon surface.

### TECHNICAL FIELD

Embodiments of the present disclosure generally relate to electronic devices and methods of forming electronic devices. In particular, embodiments of the present disclosure relate to methods of selectively depositing a liner layer on a semiconductor device.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

The semiconductor industry faces many challenges in the pursuit of device miniaturization which involves rapid scaling of nanoscale features. Such issues include the introduction of complex fabrication steps such as multiple lithography steps and integration of high-performance materials. To maintain the cadence of device miniaturization, selective deposition has shown promise as it has the potential to remove costly lithographic steps by simplifying integration schemes.

Selective deposition of materials can be accomplished in a variety of ways. A chemical precursor may react selectively with one surface relative to another surface (metallic or dielectric). Process parameters such as pressure, substrate temperature, precursor partial pressures, and/or gas flows might be modulated to modulate the chemical kinetics of a particular surface reaction. Another possible scheme involves surface pretreatments that can be used to activate or deactivate a surface of interest to an incoming film deposition precursor.

Many traditional inhibitors must be chosen based on the chemical nature of the film already present on the substrate surface. For example, some inhibitors are specific to metal vs. dielectric surface or to specific reactive groups of the substrate surface.

Thus, there remains an ongoing need in the art for methods, including bottom-up methods, that can achieve selective deposition while having minimal or no dependence on the film underneath.

### SUMMARY

One or more embodiments of the disclosure are directed methods of depositing a liner layer on a semiconductor device. In one or more embodiments, a method of depositing a liner layer on a semiconductor device includes depositing a carbon layer including carbon on a substrate of the semiconductor device, the substrate having at least one feature including a sidewall surface and a bottom surface, the carbon layer defining at least a portion of the bottom surface and having a carbon surface; and selectively depositing the liner layer on the sidewall surface over the carbon surface.

Additional embodiments of the disclosure are directed to methods of depositing a conformal layer on a semiconductor device. In one or more embodiments, a method of depositing a conformal layer on a semiconductor device includes depositing a carbon layer including carbon in a bottom second portion of a substrate feature selectively over a top first portion of the substrate feature, the top first portion having a sidewall surface and a bottom, the carbon layer having a carbon surface that defines the bottom of the top first portion; etching the carbon surface; and depositing the conformal layer on the sidewall surface of the top first portion, the conformal layer deposited on the sidewall surface selectively over the carbon surface, and the conformal layer including one or more of a nitride or a metal oxide.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method according to one or more embodiments;

FIG. 2A illustrates a cross-sectional view of a substrate having a feature according to one or more embodiments;

FIG. 2B illustrates a cross-sectional view of a substrate having a feature according to one or more embodiments;

FIG. 2C illustrates a cross-sectional view of a substrate having a feature according to one or more embodiments;

FIG. 3 illustrates a process flow diagram of an alternative method according to one or more embodiments;

FIG. 4A illustrates a cross-sectional view of a substrate having a feature according to one or more embodiments;

FIG. 4B illustrates a cross-sectional view of a substrate having a feature according to one or more embodiments;

FIG. 4C illustrates a cross-sectional view of a substrate having a feature according to one or more embodiments; and

FIG. 4D illustrates a cross-sectional view of a substrate having a feature according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” or “substrate surface”, as used herein, refers to any portion of a substrate or portion of a material surface formed on a substrate upon which film processing is performed. For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate. Substrates may have various dimensions, such as 200 mm or 300 mm diameter wafers, as well as rectangular or square panes. In some embodiments, the substrate comprises a rigid discrete material.

As used herein, the term “on” indicates that there is direct contact between elements. The term “directly on” indicates that there is direct contact between elements with no intervening elements.

As used herein, the terms “reactive compound”, “reactive gas”, “reactive species”, “precursor”, “process gas” and the like are used interchangeably to mean a substance with a species capable of reacting with the substrate or material on the substrate in a surface reaction (e.g., chemisorption, oxidation, reduction, cycloaddition). The substrate, or portion of the substrate, is exposed sequentially to the two or more reactive compounds which are introduced into a reaction zone of a processing chamber.

As used herein, the term “purge” or “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, a reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

As used in this specification and the appended claims, the term “selectively” refers to a process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

As used herein, the phrase “selectively over,” or similar phrases, means that the subject material is deposited on the stated surface to a greater extent than on another surface. In some embodiments, “selectively” means that the subject material forms on the selective surface at a rate greater than or equal to about 10×, 15×, 20×, 25×, 30×, 35×, 40×, 45× or 50× the rate of formation on the non-selected surface. In some embodiments, the passivation layer forms on the selective and does not form on the non-selective surface with a selectivity ratio of at least about 10:1, or at least about 100:1, or at least about 1000:1.

The term “on” indicates that there is direct contact between elements. The term “directly on” indicates that there is direct contact between elements with no intervening elements.

As used herein, the term “alkyl” or “alk,” alone or as part of another group, includes both straight and branched chain hydrocarbons, containing 1 to 24 carbons, or 1 to 14 carbon atoms, or 1 to 12 carbon atoms, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

The term “C₅₋₇ cyclic alkyl” as used herein includes all alkyl groups that include a ring having 5, 6, or 7 atoms.

The alkyl groups, including cyclic alkyl groups, may optionally include up to 1 to 4 substituents such as halo, for example F, Br, Cl, or I, or CF₃, alkyl, alkoxy, aryl, aryloxy, aryl(aryl) or diaryl, arylalkyl, arylalkyloxy, alkenyl, cycloalkyl, cycloalkylalkyl, cycloalkylalkyloxy, amino, hydroxy, hydroxyalkyl, acyl, heteroaryl, heteroaryloxy, heteroarylalkyl, heteroarylalkoxy, aryloxyalkyl, alkylthio, arylalkylthio, aryloxyaryl, alkylamido, alkanoylamino, arylcarbonylamino, nitro, cyano, thiol, haloalkyl, trihaloalkyl, and/or alkylthio, and the like.

Carbon-containing passivation layers may be deposited during semiconductor device manufacturing for a number of structures and processes, including as a mask material, an etch resistant material, and a trench fill material, among other applications. More specific examples of applications for carbon-containing materials include the formation of hot implant hard masks, metal gate (MG)-cut hard masks, metal gate fabrication, and reverse tone patterning, self-aligned patterning, among others. The present technology includes the selective formation of these carbon-containing materials on metal/metallic surfaces using area selective deposition (ASD).

Embodiments of the present disclosure relate to selective deposition of materials in a substrate feature by bottom-up deposition of a carbon layer in the feature. In some embodiments, the carbon layer surface is inert to one or more precursors subsequently deposited in the substrate feature, such that the precursors of the subsequent deposition may be selectively deposited on the sidewalls of the feature over the top surface of the carbon layer.

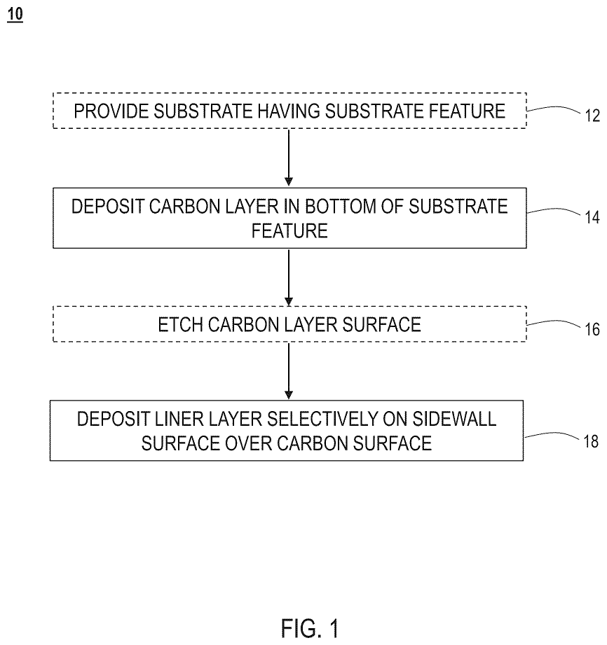

In some embodiments, a method 10 of the present disclosure has operations as illustrated in the process flow diagram of FIG. 1. Referring to FIG. 1, at optional operation 12 of method 10, in some embodiments, a substrate is provided to a processing chamber. As used herein, the term “provided” means that the substrate is made available for processing (e.g., positioned in a processing chamber). As used herein, the term “processing chamber” also includes portions of a processing chamber adjacent to the substrate surface without encompassing the complete interior volume of the processing chamber.

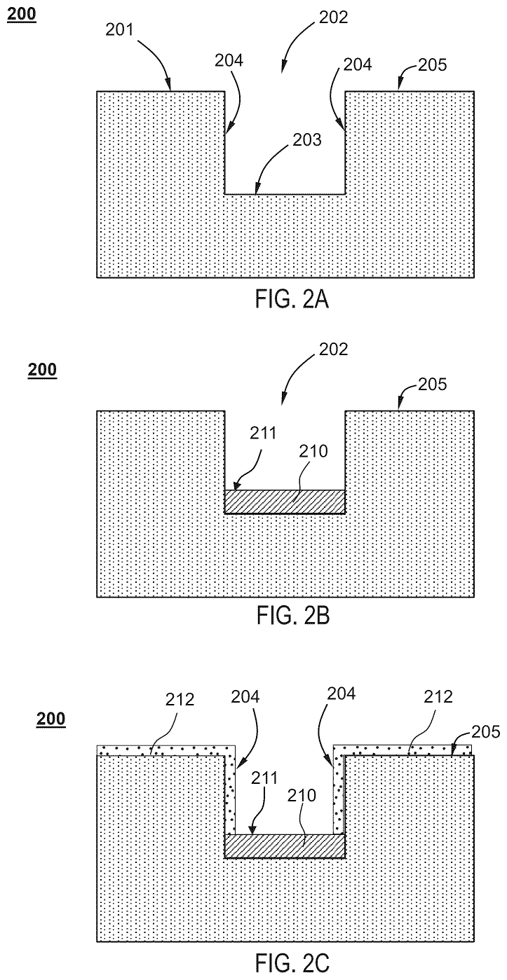

FIG. 2A schematically illustrates a substrate according to one or more embodiments of the methods provided herein. Referring to FIG. 2A, the substrate 200 may have a substrate surface 201. In some embodiments, the substrate 200 may have at least one feature 202. As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom and slot vias.

In one or more embodiments, the feature 202 represented in FIG. 2A is a trench; however, the present disclosure is not limited to trenches and may include any feature of a semiconductor substrate. The feature 201 may have a bottom surface 203, one or more sidewall surface 204, and a top surface 205.

At operation 14, in some embodiments, a carbon layer 210 may be deposited in the feature 202, as illustrated schematically in FIG. 2B. The carbon layer 210 may have a carbon surface 211. The carbon layer 210 may comprise carbon. In some embodiments, the carbon layer may consist essentially of carbon. As used herein, the term “consist essentially of” means that the carbon layer comprises at least 80%, at least 85%, at least 90%, at least 95%, at least 98%, or at least 99% carbon. In some embodiments, the carbon layer may consist of carbon. In some embodiments, the carbon layer 210 is pure carbon. In some embodiments, the carbon layer 210 is an insulating carbon layer.

In one or more embodiments, the carbon layer 210 may comprise amorphous carbon (commonly referred to as a-C). As used herein, the term amorphous carbon also includes hydrogenated amorphous carbon (a-C:H) and further includes any microstructure such as, for example, diamond-like amorphous carbon (DLC), polymer-like amorphous carbon (PLC), or any combination of these microstructures. Further, the term amorphous carbon may be used without limitation as to the percentage of the material having a particular polycrystalline microstructure. The DLC microstructure provides a film with a higher density and hardness and a lower hydrogen (H) content than a PLC microstructure. In some embodiments, the carbon layer 210 may consist essentially of amorphous carbon. In some embodiments, the carbon layer may consist of amorphous carbon.

In one or more embodiments, the carbon layer 210 may comprise amorphous hydrogenated carbon (commonly referred to as a-C:H or α-C:H). Amorphous hydrogenated carbon is considered a carbon material with no long-range crystalline order and which may contain substantial hydrogen content, for example on the order of about 10 to 45 atomic % of hydrogen. Amorphous carbon has been observed to have chemical inertness, optical transparency, and good mechanical properties. While a-C:H films can be deposited via various techniques, plasma enhanced chemical vapor deposition (PECVD) is widely used due to cost efficiency and film property tunability. In some embodiments, the carbon layer 210 may consist essentially of amorphous hydrogenated carbon. In some embodiments, the carbon layer may consist of amorphous hydrogenated carbon.

In one or more embodiments, the carbon layer 210 is deposited in a bottom up gap fill process. As used herein, the term “bottom up gap fill process” and similar terms, means that the material deposits on the bottom surface 203 of the feature 202 and grows upward toward the top surface 205 of the feature 202. The carbon layer 210 may be deposited to any particular depth from the bottom surface 203. For example, in some embodiments, as illustrated in FIG. 2B, the carbon layer 210 is deposited such that the carbon surface 211 is below the top surface 205 of the feature 202. In some embodiments, the carbon layer 210 may be deposited by an etch back process which forms the carbon layer 210 selectively at the bottom surface 203 of the feature 202. For example, the carbon layer 210 may be deposited on the bottom surface 203 of the feature, the sidewall surface 204 of the feature, and the top surface 201 of the feature, and subsequently etched back such that the carbon layer 210 remains on the bottom surface 203.

In some embodiments, a thickness of the carbon layer 210 is in a range of from about 1 nm to about 100 nm. In some embodiments, a thickness of the carbon layer 210 is about 50 nm or less. In some embodiments, a thickness of the carbon layer 210 is about 25 nm or less. In some embodiments, the thickness of the carbon layer 210 is about 20 nm or less, or about 15 nm or less, or about 10 nm or less, or about 5 nm or less.

In one or more embodiments, the carbon layer 210 may be deposited by any suitable technique known to the skilled artisan. For example, carbon layer 210 may be deposited using a suitable chemical vapor deposition (CVD) or plasma enhanced chemical vapor deposition (PECVD) process based on a hydrocarbon gas or mixture of hydrocarbon gases such as acetylene (C₂H₂), propylene (C₃H₆), or the like, and may also include hydrogen (H₂).

Chemical vapor deposition (CVD) is one of the most common deposition processes employed for depositing layers on a substrate. CVD is a flux-dependent deposition technique that uses precise control of the substrate temperature and the precursors introduced into the processing chamber in order to produce a desired layer of uniform thickness. The reaction parameters become more critical as substrate size increases, creating a need for more complexity in chamber design and gas flow technique to maintain adequate uniformity.

The carbon layer 210 may also be deposited by a suitable atomic layer deposition (ALD) or plasma enhanced atomic layer deposition (PEALD) process based on, for example, a hydrocarbon gas or mixture of hydrocarbon gases. The skilled artisan will be familiar with deposition methods of carbon layers on semiconductor substrates.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness. In some embodiments, there may be two reactants, A and B, which are alternatingly pulsed and purged. In other embodiments, there may be three or more reactants, A, B, and C, which are alternatingly pulsed and purged.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In one or more embodiments, at optional operation 16 of method 10, in some embodiments, the carbon surface 211 is etched. The etching may decrease the height of the carbon surface relative to the bottom surface 203 of the feature 202. The carbon surface 211 may be etched by any suitable etch process known to the skilled artisan that is compatible with a carbon material. In some embodiments, the etching 16 uses a wet etch process, such as aqueous alkaline media, non-limiting examples including potassium hydroxide (KOH), sodium hydroxide (NaOH), or tetramethylammonium hydroxide (TMAH) solutions. In some embodiments, a dry etch process is used. For example, the carbon surface 211 may be exposed to H₂, NF₃, and/or NHs plasma species, e.g., plasma-excited hydrogen and fluorine species. The etch process may be plasma or thermally based. The plasma etch process can use any suitable plasma (for example, conductively coupled plasma, inductively coupled plasma, or microwave plasma) known to the skilled artisan.

In some embodiments, the etching may control surface termination of carbon surface 211. For example, the etching may form terminal hydrogen groups (—H groups) or terminal methyl groups (—CH₃ groups) on carbon surface 211. In some embodiments, the etching may remove, or reduce the amount of, terminal hydroxide groups (—OH groups) that were present on the carbon surface 211 prior to the etching. Without intending to be bound by the theory, it is believed that terminal hydrogen groups or terminal methyl groups can increase the inertness of the carbon surface 211 to a subsequent deposition of precursors in the feature 202. For example, a transition state energy for the reaction of a precursor, such as a nitride or metal oxide precursor, forming a bond with the carbon surface, may be higher when the carbon surface is hydrogen-terminated or methyl-terminated compared to, for example, when the carbon surface is hydroxyl-terminated.

In some embodiments, the etching may remove about 1 nm or less from the carbon surface 211. In some embodiments, the etching may remove a single monolayer, or portions of a single monolayer, from the carbon surface 211. In some embodiments, the etching comprises plasma etching and the plasma etching may be performed for a time period of 30 seconds or less, or 10 seconds or less, or 5 seconds or less, or 3 seconds or less.

In some embodiments, the plasma etching comprises a hydrogen (H₂) plasma. In some embodiments, the plasma is generated using a remote plasma source (RPS). In some embodiments, the plasma comprises a hydrogen (H₂) plasma that is generated uses an RPS. In some embodiments, the hydrogen (H₂) plasma reduces or eliminates-OH groups on the carbon surface 211.

Referring to FIG. 2C, at operation 18 of method 10, in some embodiments, a liner layer 212 is selectively deposited on the sidewall surface 204 over the carbon surface 211. In some embodiments, the liner layer 212 is deposited on both a sidewall surface 204 and a top surface 205 of feature 202. In some embodiments, substantially no liner layer is deposited on the carbon surface 211. In some embodiments, the liner layer forms on the sidewall surface 204, and optionally on the top surface 205, at a rate of at least 10×, or at least 20×, or at least 100×, or at least 1000×, relative to the rate the liner forms on the carbon surface 211.

In some embodiments, a thickness of the liner layer deposited on the sidewall surface 204, and optionally on the top surface 205, of feature 202, is at least 10×, or at least 20×, or at least 100×, or at least 1000×, greater compared to a thickness of the liner layer on the carbon surface 211.

In some embodiments, the liner layer 212 is a conformal liner layer. In some embodiments, the liner 212 is a superconformal liner layer. As used herein, the term “superconformal liner layer” means that the liner layer has a greater thickness near the top of the feature than near the bottom of the feature.

In some embodiments, the liner layer 212 comprises one or more of a nitride or a metal oxide. In some embodiments, the nitride comprises silicon nitride (SIN). As used throughout the present disclosure, when a chemical composition having two or more elements is provided, for example “silicon nitride” or “SiN,” does not imply any particular stoichiometry of the individual elements, unless expressly provided as such. In some embodiments, the nitride comprises aluminum nitride (AlN).

In some embodiments, the liner layer 212 comprises a metal oxide. Non-limiting examples of metal oxides contemplated for the liner layer 212 include aluminum oxide (AlO), hafnium oxide (HfO), titanium oxide (TiO₂), and combinations thereof.

In some embodiments, the liner layer 212 comprises aluminum oxide (AlO) and the liner layer 212 deposition is a dry process. As used herein, the term “dry process” means that the AlO deposition is performed without the use of water. In some embodiments, the aluminum oxide (AlO) comprises a stoichiometry of Al₂O₃.

In some embodiments, following the selective deposition 18 of the liner layer 212, the carbon layer 210 is removed from the bottom of the feature 202. In some embodiments, the etching 16 of the carbon layer surface, selective deposition 18 of the liner layer on the sidewall surfaces, and removal of the carbon layer are performed in the same processing chamber.

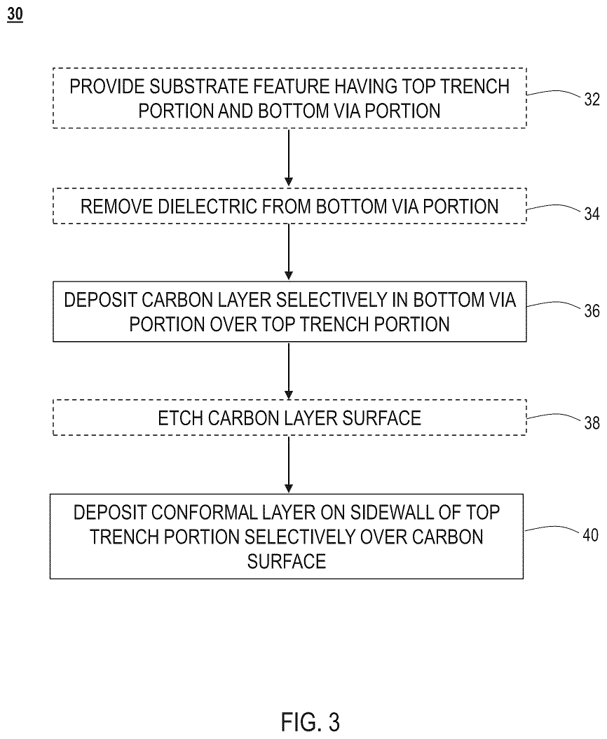

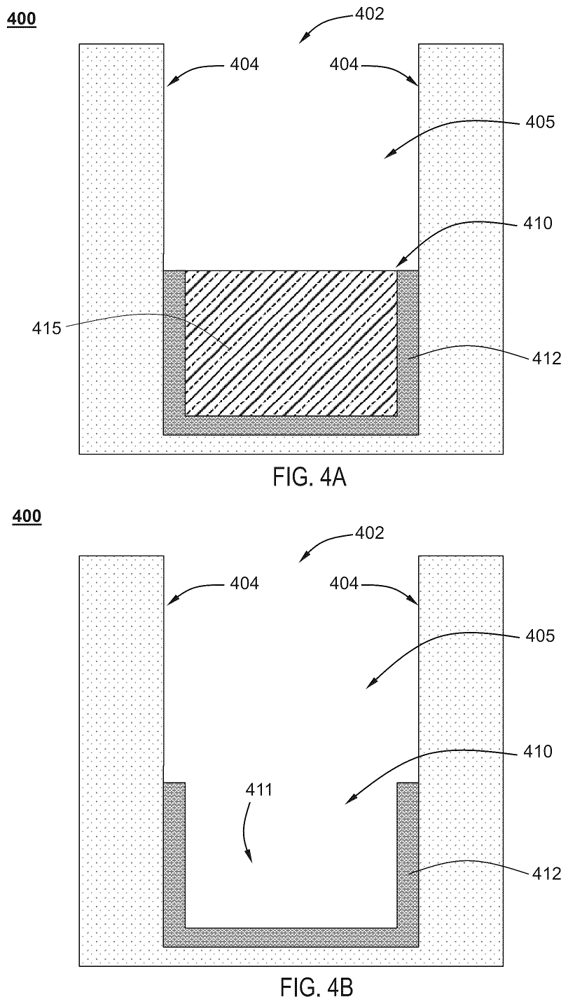

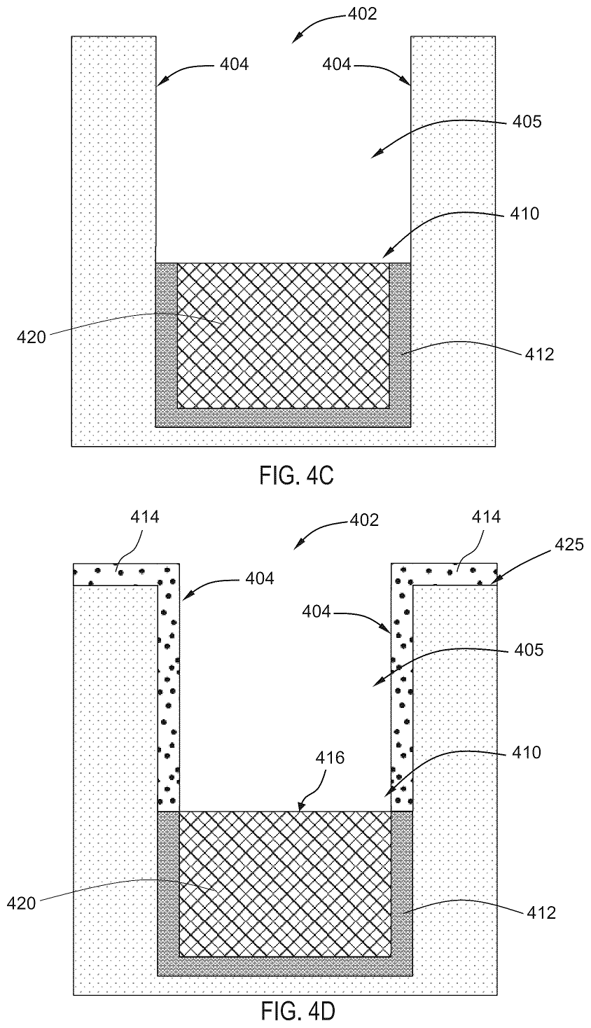

Some embodiments of the present disclosure relate to a method of depositing a conformal layer on a semiconductor device, as for example illustrated schematically in the process flow diagram of FIG. 3. At optional operation 32 of method 30, according to some embodiments, a substrate is provided to the processing chamber. FIG. 4A schematically illustrates an example substrate 400 according to some embodiments of method 30. FIG. 4A illustrates a substrate 400 having a feature 402, the feature 402 including a top first portion 405 and a bottom second portion 410. The first portion 405 may have one or more sidewalls 404. In some embodiments, as illustrated in FIG. 4A, the second portion 410 may have a conformal barrier layer 412 thereon, but the conformal barrier layer 412 is optional and may or may not be present according to various embodiments and technical applications of the present disclosure.

As illustrated schematically in FIG. 4A, the first portion 405 and second portion 410 may have the same dimensions in a lateral dimension, such that the widths of first portion 405 and second portion 410 are substantially the same and the sidewalls 404 of the trench portion 404 are substantially colinear with sidewalls of the second portion 410. In some embodiments, the top first portion 405 and bottom second portion 410 may independently have different widths, depths, and other dimensions, as the skilled artisan will appreciate.

In some embodiments, the second portion 410 may be filled with a dielectric material 415. The dielectric material 415 may be any suitable dielectric material known to the skilled artisan. A “dielectric material,” as used herein, refers to an electrical insulator material that can be polarized by an applied electric field. Non-limiting examples of dielectric material include silicon oxide (SiOₓ), silicon nitride (SiₓN_{y}), silicon (Si), silicon oxynitride (SiON), carbides, oxycarbides, nitrides, oxynitrides, oxycarbonitrides, polymers, phosphosilicate glass, fluorosilicate (SiOF) glass, organosilicate glass (SiOCH), aluminum oxide (AlOₓ), hafnium oxide (HfOₓ), zirconium oxide (ZrO₂), titanium oxide (TiOₓ), titanium nitride (TiN), tantalum oxide (TaₓO₅), yttrium oxide (Y₂O₃), lanthanum oxide (La₂O₃), aluminum nitride (AlN), magnesium oxide (MgO), calcium fluoride (CaF₂), lithium fluoride (LiF), strontium oxide (SrO), barium oxide (BaO), hafnium silicate (HfSiO₄), lanthanum aluminate (LaAlO₃), niobium pentoxide (Nb₂O₅), barium titanate (BaTiO₃), strontium titanate (SrTiO₃), bismuth titanate (Bi₄Ti₃O₁₂), lead zirconium titanate (Pb(Zr, Ti)O₃), calcium copper titanate (CaCu₃Ti₄O₁₂), lithium niobate (LiNbO₃), barium titanate (BaTiO₃), and potassium niobate (KNbO₃). In one or more embodiments, the dielectric material is silicon germanium (SiGe).

At optional operation 34 of method 30, as illustrated in FIG. 4B, according to one or more embodiments, the dielectric material 415 is removed from the second portion 410 of the feature 402 to leave an opening 411. The dielectric material 415 may be removed using any suitable method known to the skilled artisan, for example using any of the etching methods described herein. After removal of the dielectric material 415, the substrate 400 may have a structure as illustrated in FIG. 4B.

Referring to FIG. 4C, at operation 36 of method 30, in some embodiments, a carbon layer 420 is deposited selectively in the bottom second portion 410 over the top first portion 405. In some embodiments, the carbon layer 420 may comprise carbon, or consist essentially of carbon, or consist of carbon. In some embodiments, the carbon layer 420 may comprise amorphous carbon, or consist essentially of amorphous carbon, or consist of amorphous carbon. In some embodiments, the carbon layer 420 may comprise amorphous hydrogenated carbon, or consist essentially of amorphous hydrogenated carbon, or consist of amorphous hydrogenated carbon. In some embodiments, the carbon layer 420 is pure carbon.

In some embodiments, the carbon layer may comprise a porous carbon. In some embodiments, the porous carbon is a nanoporous carbon. In some embodiments, the porous carbon is a microporous carbon.

In some embodiments, the carbon layer is a non-porous carbon. In some embodiments, the non-porous carbon may have less than about 20% pores, or less than about 10% pores, or less than about 5% pores, or less than about 2% pores, or less than about 1% pores, as measured on a per-volume basis. The non-porous carbon may have substantially no pores. In some embodiments, the non-porous carbon may have no pores. In some embodiments, the carbon layer is an insulating carbon layer.

In some embodiments, the carbon layer 420 is deposited in a bottom-up gap fill process. The bottom-up gap fill process may, in one or more embodiments, fill the bottom second portion 410, and deposit no carbon layer 420, or substantially very little carbon layer 420, in the top first portion 405.

Referring to FIG. 4D, at optional operation 38, in some embodiments, a surface 416 of carbon layer 420 may be etched. The etching may be accomplished using any suitable etching method known to the skilled artisan compatible with a carbon material, such as any of the etching methods described herein. In some embodiments, the etching may remove about 1 nm or less from the carbon surface 416. In some embodiments, the etching may remove substantially only the portion of the carbon layer 420 that has been deposited into the first portion 405 of the at least feature 402. In some embodiments, the etching may control surface termination of carbon surface 416. For example, the etching may form terminal hydrogen groups (—H groups) or terminal methyl groups (—CH₃ groups) on carbon surface 416. In some embodiments, the etching may remove, or reduce the amount of, terminal hydroxide groups (—OH groups) that were present on the carbon surface 416 prior to the etching. In some embodiments, the etching comprises plasma etching and the plasma etching may be performed for a time period of 30 seconds or less, or 10 seconds or less, or 5 seconds or less, or 3 seconds or less.

In some embodiments, the plasma etching comprises a hydrogen (H₂) plasma. In some embodiments, the plasma is generated using a remote plasma source (RPS). In some embodiments, the plasma comprises a hydrogen (H₂) plasma that is generated uses an RPS. In some embodiments, the hydrogen (H₂) plasma reduces or eliminates-OH groups on the carbon surface 211.

Referring to FIG. 4D, at operation 40, in some embodiments, a conformal layer 414 is deposited selectively on the top first portion 405 over the carbon surface 416. In some embodiments, the conformal layer 414 is deposited on both a sidewall surface 404 of trench 405 and a top surface 425 of feature 402. In some embodiments, substantially no conformal layer is deposited on the carbon surface 416. In some embodiments, the conformal layer forms on the sidewall surface 404, and optionally the top surface 425, of feature 402, at a rate of at least 10×, or at least 20×, or at least 100×, or at least 1000×, relative to the rate the conformal layer 414 forms on the carbon surface 416. In some embodiments, a thickness of the conformal layer 414 deposited on the sidewall surface 404, and optionally on the top surface 405, is at least 10×, or at least 20×, or at least 100×, or at least 1000×, greater compared to a thickness of the conformal layer on the carbon surface 416.

In some embodiments, the conformal layer 414 comprises silicon nitride (SiN). In some embodiments, the conformal layer 414 comprises aluminum nitride (AlN). In some embodiments, the conformal layer 414 comprises a metal oxide. Non-limiting examples of metal oxides contemplated herein include aluminum oxide (AlO), hafnium oxide (HfO), titanium oxide (TiO₂), and combinations thereof. In some embodiments, the conformal layer 414 comprises aluminum oxide (AlO) and the deposition of the conformal layer 414 comprises a dry process. In some embodiments, the aluminum oxide (AlO) comprises a stoichiometry of Al₂O₃.

In some embodiments, the carbon layer 420 is removed after the deposition of the conformal layer 414. In some embodiments, the etching 38 of the carbon layer surface, the selective deposition 40 of the conformal layer on the sidewalls of the top trench portion, and the removal of the carbon layer are performed in the same processing chamber.

In some embodiments of the methods provided herein, the methods may comprise removing one or more precursor effluent from the substrate. The removing one or more precursor effluent may comprise purging of the processing chamber. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of one or more reactive species by any suitable technique including, but not limited to, moving the substrate through a gas curtain to a portion or sector of the processing chamber that contains none or substantially none of the one or more reactive species. In some embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), neon (Ne), and argon (Ar).

In some embodiments, the processing region is in a modular system comprising multiple chambers which perform various functions including substrate center-finding and orientation, degassing, annealing, deposition and/or etching. According to one or more embodiments, the modular system includes at least a first processing chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation, and other substrate processes. By carrying out processes in the processing chamber of a modular system, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, the inert gas is used to purge or remove some or all of the reactants (e.g., reactant). According to one or more embodiments, the inert gas is injected at the exit of the processing chamber to prevent reactants (e.g., reactant) from moving from the processing chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

In a spatial ALD process, the reactive gases are flowed into different processing regions within a processing chamber. The different processing regions are separated from adjacent processing regions so that the reactive gases do not mix. The substrate can be moved between the processing regions to separately expose the substrate to the reactive gases. During substrate movement, different portions of the substrate surface, or material on the substrate surface, are exposed to the two or more reactive gases so that any given point on the substrate is substantially not exposed to more than one reactive gas simultaneously. As will be understood by those skilled in the art, there is a possibility that a small portion of the substrate may be exposed to multiple reactive gases simultaneously due to diffusion of the gases within the processing chamber, and that the simultaneous exposure is unintended, unless otherwise specified.

A “pulse” or “dose” as used herein refers to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds.

The durations for each pulse/dose are variable and may be adjusted to accommodate, for example, the volume capacity of the processing chamber as well as the capabilities of a vacuum system coupled thereto. Additionally, the dose time of a reactive gas may vary according to the flow rate of the reactive gas, the temperature of the process gas, the type of control valve, the type of process chamber employed, as well as the ability of the components of the process gas to adsorb onto the substrate. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

Once the passivation layer is deposited, the method may optionally include further processing (e.g., bulk deposition of a dielectric film). In some embodiments, the further processing may be an ALD process.

The disclosure provides that the processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor or controller, transforms the general-purpose computer into a specific purpose computer (controller) that controls the chamber operation such that the processes are performed. The process can be stored on non-transitory computer readable medium including instructions, that, when executed by a controller of a substrate processing chamber, causes the substrate processing chamber to perform the operations of: deposit a carbon layer comprising carbon on a substrate of a semiconductor device, the substrate having at least one feature, and the carbon layer having a surface; and selectively deposit a liner layer on one or more sidewall surfaces of the feature over the carbon surface.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a liner layer on a semiconductor device, the method comprising:
depositing a carbon layer comprising carbon on a substrate of the semiconductor device, the substrate having at least one feature including a sidewall surface and a bottom surface, the carbon layer defining at least a portion of the bottom surface and having a carbon surface; and
selectively depositing the liner layer on the sidewall surface over the carbon surface.

2. The method of claim 1, wherein the liner layer comprises one or more of a nitride or a metal oxide.

3. The method of claim 2, wherein the nitride comprises silicon nitride or aluminum nitride.

4. The method of claim 2, wherein the metal oxide comprises aluminum oxide, hafnium oxide, or titanium oxide.

5. The method of claim 1, wherein substantially no liner layer is deposited on the carbon surface.

6. The method of claim 1, wherein a ratio of the liner layer on the sidewall surface to the carbon surface is about 10:1 or greater.

7. The method of claim 1, wherein a thickness of the carbon layer is in a range of from about 1 nm to about 100 nm.

8. The method of claim 1, further comprising etching the carbon surface before depositing the liner layer.

9. The method of claim 8, wherein the etching comprises plasma etching.

10. The method of claim 8, wherein the etching forms terminal hydrogen groups and/or terminal C₁₋₁₄ alkyl groups on the carbon surface.

11. The method of claim 8, wherein the etching removes at least a portion of the carbon layer from the sidewall surface and a top surface of the at least one or more feature.

12. The method of claim 1, wherein the etching removes less than about 90% of an original thickness of the carbon layer.

13. The method of claim 1, wherein the carbon layer is deposited using a bottom up gap fill process.

14. The method of claim 13, further comprising etching back the carbon layer to form the carbon layer selectively on the bottom surface over the sidewall surface and a top surface of the at least one feature.

15. The method of claim 1, wherein the carbon layer comprises non-porous carbon.

16. A method of depositing a conformal layer on a semiconductor device, the method comprising:
depositing a carbon layer comprising carbon in a bottom second portion of a substrate feature selectively over a top first portion of the substrate feature, the top first portion having a sidewall surface and a bottom, the carbon layer having a carbon surface that defines the bottom of the top first portion;
etching the carbon surface; and
depositing the conformal layer on the sidewall surface of the top first portion, the conformal layer deposited on the sidewall surface selectively over the carbon surface, and the conformal layer comprising one or more of a nitride or a metal oxide.

17. The method of claim 16, wherein the conformal layer is selected from the group consisting of silicon nitride, aluminum oxide, aluminum nitride, hafnium oxide, titanium oxide, silicon oxynitride, silicon oxycarbonitride, and combinations thereof.

18. The method of claim 16, wherein a ratio of the conformal layer on the sidewall surface to the carbon surface is about 10:1 or greater.

19. The method of claim 16, wherein a thickness of the carbon layer is in a range of from about 1 nm to about 100 nm.

20. The method of claim 16, wherein the etching comprises plasma etching.
